(19) United States
(12) Patent Application Publication
(10) Pub. No.: US 2013/0000693 A1
(43) Pub. Date: Jan. 3, 2013

(54) Solar Positioning System and Method

(75) Inventors: Tamsyn Peronel Waterhouse, San Francisco, CA (US); Jonathan Peter Switkes, San Jose, CA (US); John Stuart Fitch, Los Altos, CA (US); Tim Allen, Santa Cruz, CA (US); Ross Koningstein, Atherton, CA (US)

(73) Assignee: Google Inc., Mountain View, CA (US)

(21) Appl. No.: 13/173,676

(22) Filed: Jun. 30, 2011

(51) Int. Cl. F24J 2/38; F24J 2/52; H01L 31/052

(52) U.S. Cl. 136/246; 126/605; 126/576

(57) ABSTRACT

An apparatus for positioning an object, for example, a solar energy capture device, can include a frame, the object, a joint, and at least two linear actuators. The joint connects the object to the frame and allows the object to rotate relative to the frame. The first and second linear actuators are coupled to the object. When the first and second actuators are actuated in combination, the object rotates about a pitch axis. When the first and second actuators are actuated differentially, the object rotates about a roll axis.

### BACKGROUND OF THE INVENTION

1. Field of the Invention

The present invention is generally directed to apparatuses and methods for positioning an object and, more particularly, to apparatuses and methods for positioning a solar energy capture device using linear actuators.

2. Background

For numerous reasons—including lowering the concentrations of greenhouse gases, strengthening the ozone, reducing global warming effects, and obtaining a sustainable source of energy—energy sources other than fossils fuels are becoming more popular. One common alternative energy source is solar energy.

There are two common systems for generating electricity from solar energy: a thermal system and a photovoltaic system. In a thermal system, a mirror assembly reflects sunlight onto a receiver. The receiver, in turn, may heat a fluid or gas. In some thermal systems, the receiver heats the fluid or gas to power a turbine to create electricity, for example, by turning a fluid into a gas. In other thermal systems, the receiver can simply heat the fluid or gas for process heat applications. In photovoltaic systems, a photovoltaic panel converts sunlight into electricity. In both systems, the position of the solar energy capture device—the mirror assembly in a thermal system or the photovoltaic panel in a photovoltaic system, for example—should continuously change as the position of the sun changes. For example, as the sun moves, the orientation of the mirror assembly needs to change to keep the reflected light focused on the receiver. In photovoltaic systems, the photovoltaic panel should be reoriented to ensure that the panel is orthogonal to the direction of the sunlight to achieve peak efficiency.

In many of these systems, a solar energy capture devices is coupled to a frame post by two direct-drive motors located at the top of the post. One of the motors is aligned to change the elevation angle of the solar energy capture device, and the other motor is aligned to change the azimuth angle of the solar energy capture device. The weight of the motors and their relatively high position on the post can require a frame that is large and, consequently, one that may be expensive and heavy. This requirement can make implementation and scaling of many solar energy systems unduly expensive, especially when increasing the size of solar energy capture devices and the number of devices deployed in an array.

### BRIEF SUMMARY OF THE INVENTION

In one embodiment, an apparatus for receiving sunlight includes a frame, a solar energy capture device, a joint, and first and second linear actuators. The joint connects the solar energy capture device to the frame and allows the solar energy capture device to rotate relative to the frame. The first and second linear actuators are coupled to the solar energy capture device. The first and second actuators actuate in combination to rotate the solar energy capture device about a pitch axis, and the first and second actuators actuate differentially to rotate the solar energy capture device about a roll axis. The solar energy capture device may include a mirror assembly or a photovoltaic panel.

In another embodiment, an apparatus includes a frame having a lateral axis and a longitudinal axis, a solar energy capture device, a joint assembly, a first variable length actuator, and a second variable length actuator. The joint assembly connects the solar energy capture device to the frame, while allowing rotation of the solar energy capture device relative to the frame. The joint assembly includes a lower portion connected to the frame to allow rotation of the solar energy capture device about the lateral axis. The joint assembly also includes an upper portion connected to the solar energy capture device and the lower portion to allow rotation of the solar energy capture device about the longitudinal axis. The first variable length actuator has a first pivot end coupled to the solar energy capture device on a first side of the joint assembly, and the second variable length actuator has a second pivot end coupled to the solar energy capture device on a second side of the joint assembly opposite the first pivot end. The first and second actuators actuate in combination to rotate the solar energy capture device about the lateral axis and actuate differentially to rotate the solar energy capture device about the longitudinal axis.

In one embodiment, an apparatus for positioning an object at a desired pitch angle and a desired roll angle includes a frame, an object, a joint, a first linear actuator, and a second linear actuator. The joint connects to the object and the frame to allow rotation of the object relative to the frame. The first and second linear actuators each have a variable length member. The variable length members are coupled to the object and the frame. The lengths of the first and second variable length members are simultaneously and equally changed to rotate the object about a pitch axis, while the length of the first variable length member is differentially changed relative to the length of the second variable length member to rotate the object about a roll axis. The object can be a solar energy capture device.

Methods for using apparatuses according to embodiments described herein are also provided.

In one embodiment, a method for positioning a solar energy capture device comprises moving the solar energy capture device to a desired orientation by collectively actuating first and second linear actuators to rotate the solar energy capture device about a pitch axis and by differentially actuating the first and second linear actuators to rotate the solar energy capture device about a roll axis. The first and second linear actuators are coupled to the solar energy capture device and a frame.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts a block diagram of an apparatus that positions an object at a desired orientation according to an embodiment of the present invention.

FIG. 2 illustrates a perspective view of an apparatus that positions a solar energy capture device at a desired orientation according to an embodiment of the present invention.

FIG. 3 illustrates an enlarged perspective view of a joint as illustrated in FIG. 2 according to an embodiment of the present invention.

FIG. 4 illustrates a perspective view of an apparatus that positions a solar energy capture device at a desired orientation according to an embodiment of the present invention.

FIG. 5 illustrates a perspective view of an apparatus that positions a solar energy capture device at a desired orientation according to an embodiment of the present invention.

FIG. 6 illustrates a front perspective view of an apparatus that positions a solar energy capture device at a desired orientation according to an embodiment of the present invention.

FIG. 7 illustrates a rear perspective view of an apparatus that positions a solar energy capture device at a desired orientation according to an embodiment of the present invention.

FIG. 8 illustrates a process flowchart depicting a method of positioning a solar energy capture device according to an embodiment of the present invention.

FIG. 9 illustrates a block diagram depicting a closed loop configuration for moving solar energy capture device 100 according an embodiment of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION OF THE INVENTION

In the detailed description that follows, references to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

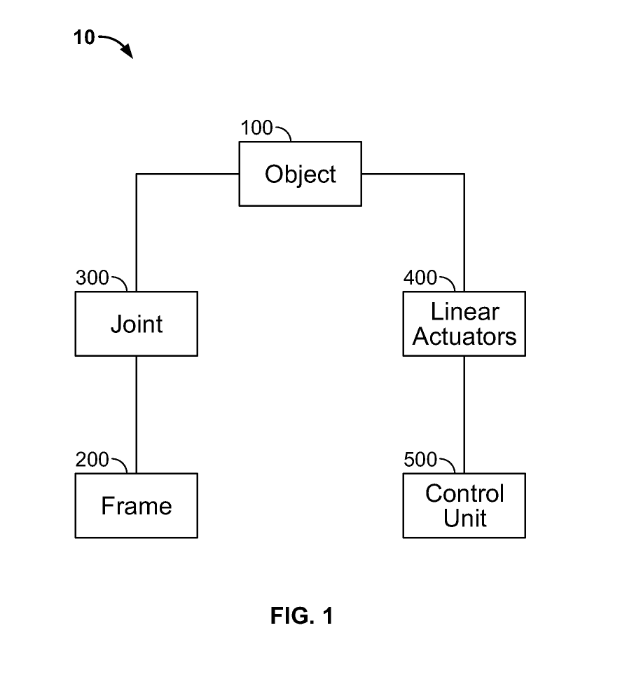

FIG. 1 is a block diagram of an apparatus 10 that positions an object 100 at a desired orientation according to an embodiment of the present invention. In one embodiment, apparatus 10 includes a frame 200, a joint 300, at least two linear actuators 400, and a control unit 500. Object 100 may be any object that has at least two different desired orientations. For example, object 100 may be a solar energy capturing device such as a mirror assembly used with a solar thermal system or a photovoltaic panel used with a solar photovoltaic system. Object 100 can also be other types of object having at least two different desired orientations such as a communication antenna, a weapon platform, a directed-energy appliance, and any other suitable object.

In one embodiment, frame 200 is adapted to structurally support and position object 100. Frame 200 can be figured to directly or indirectly contact a mounting surface, for example, the ground, a roof, a wall, an overhead surface, or other suitable surface. Frame 200 elevates object 100 above the mounting surface. Frame 200 may define a lateral axis that runs from the left side of frame 200 to the right side of frame 200, and define a longitudinal axis that runs from the front of frame 200 to the back of frame 200. The longitudinal axis may be orthogonal to the lateral axis. Frame 200 can be made of any suitable rigid material having sufficient strength to support object 100. For example, frame 200 can be formed from square tubing, piping, or channel made of iron, aluminum, composites (e.g., carbon fiber composites), wood, plastic, or any other suitable material.

Joint 300 rotatably couples object 100 to frame 200 such that object 100 can rotate relative to frame 200. Joint 300 defines a pitch axis PA and a roll axis RA. In one embodiment, pitch axis PA is parallel to the lateral axis of frame 200, and roll axis RA can project on the longitudinal axis of frame 200 and may be planar with the longitudinal axis of frame 200. When coupled to joint 300, object 100 can rotate about pitch axis PA and roll axis RA. Joint 300 can be a universal joint (U-joint), a ball and socket joint, or any other type of joint that has at least two degrees of freedom. In one embodiment, joint 300 can be made of one or more rotating members.

In one embodiment, apparatus 10 includes at least two linear actuators 400. Linear actuators 400 are coupled to object 100 and are adapted to position the object relative to a source. Linear actuators 400 can include a drive component, for example, a motor or hydraulic pump and cylinder, and a variable length member that can selectively change its length. Linear actuators 400 can selectively apply a force to object 100 by changing the length of the variable length member, which rotates object 100 about pitch axis PA and roll axis RA. Particularly, as further described below, in one embodiment linear actuators 400 may collectively rotate object 100 about pitch axis PA and differentially rotate object 100 about roll axis RA. In some embodiments, apparatus 10 may include two, three, or more than three linear actuators. In one embodiment, each linear actuator 400 may comprise a cable actuation mechanism including a motor and a cable, a hydraulic piston, a scissor-jack, a linear screw drive, or any other suitable linear actuator having a variable length member. Linear actuators 400 coupled to object 100 may comprise the same type or different types of actuators. For example, in some embodiments, first and second linear actuators 400 may both comprise a cable-actuated mechanism. In other embodiments, for example, a first linear actuator 400 may comprise a cable actuator and a second linear actuator 400 may comprise a hydraulic piston actuator.

In one embodiment, apparatus 10 includes control unit 500. Control unit 500 includes a processor and memory. Control unit 500 is operatively connected to linear actuators 400. Control unit 500 is adapted to generate and manipulate control signals that cause the variable length member of linear actuators 400 to change lengths and, thus, change the orientation of object 100.

Apparatus 10 may be used as an individual unit for positioning a single object 100 or as a series of units in an array for positioning a plurality of objects 100. For example, in one embodiment, a plurality of apparatuses 10 each having a solar energy capture device 100 may be arranged in a solar field. In one embodiment such as a thermal system, the plurality of apparatuses 10 may be arranged to concentrate the reflected sunlight onto a receiver that powers a heat engine which, in turn, drives a rotary generator, for example, a turbine. In one embodiment, apparatuses 10 in an array can be arranged in one or more linear or arcuate rows.

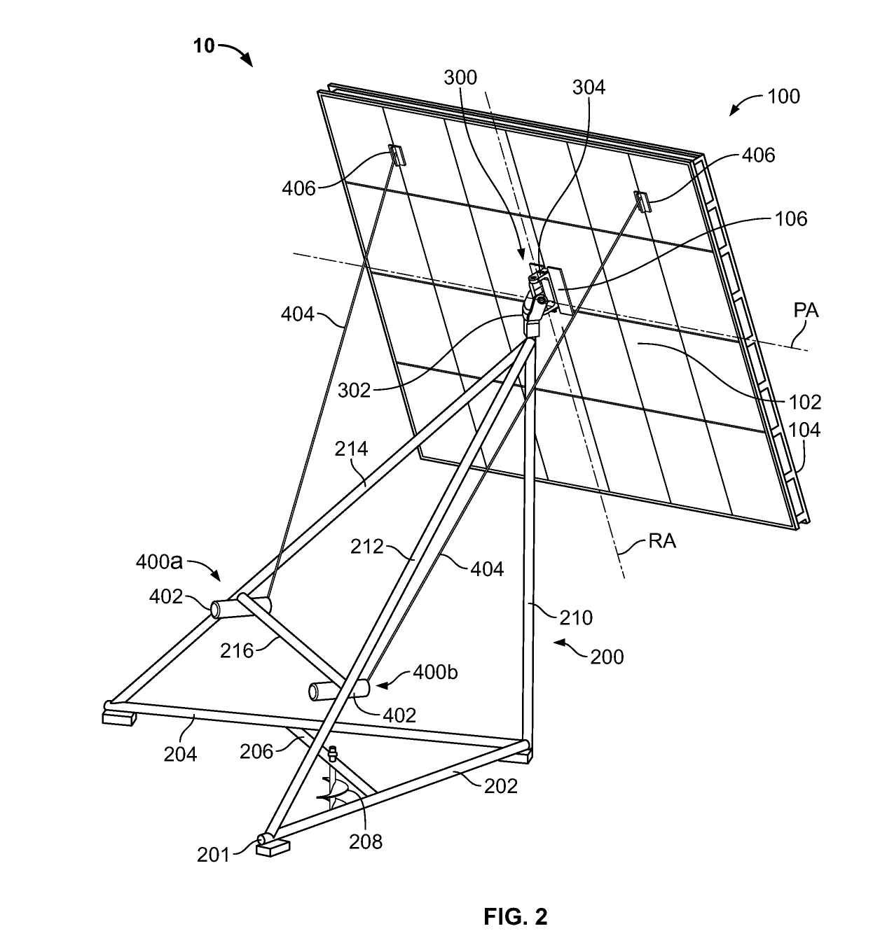

FIG. 2 illustrates a perspective view of apparatus 10 according to an embodiment of the present invention. As illustrated in FIG. 2, object 100 is a solar energy capture device, for example, a mirror assembly or a photovoltaic panel. Solar energy capture device 100 has a back surface 102 and a front surface 104. Solar energy capture device 100 can also include a reinforcement plate 106 coupled to back surface 102. Reinforcement plate 106 strengthens back surface 102 of solar energy capture device 100 and may be used as an interface with joint 300. For example, reinforcement plate 106 may act as a mounting plate for joint 300.

Apparatus 10 also includes frame 200. As shown in FIG. 2, frame 200 includes a base portion 201. Base portion 201 may be any suitable configuration to support frame 200 on the mounting surface, and to allow stable positioning of object 100. In one embodiment, base portion 201 is triangular and configured to contact a mounting surface, for example, the ground. The base portion of frame 200 includes a right diagonal strut 202 and a left diagonal strut 204. Right diagonal strut 202 and left diagonal strut 204 are angled towards each other such that they join at the front of apparatus 10. The base portion can also include a cross strut 206 that runs between right diagonal strut 202 and left diagonal strut 204. Cross strut 206 prevents right diagonal strut 202 and left diagonal strut 204 from moving towards or away from each other. In an embodiment, the base portion can include a surface anchor 208 that fixedly secures frame 200 to the mounting surface. For example, in one embodiment, surface anchor 208 can be a cork screw or helical ground anchor as illustrated in FIG. 2. In other embodiments, surface anchor 208 can be any other type of suitable fasteners, for example, one or more bolts or screws. In another embodiment, surface anchor 208 may include one or more posts that extend into the mounting surface.

In one embodiment, frame 200 further includes a vertically extending front strut 210. In an embodiment, front strut 210 extends upward from the intersection of right diagonal strut 202 and left diagonal strut 204. Frame 200 also includes right diagonal vertical strut 212 and left diagonal vertical strut 214. Right diagonal vertical strut 212 extends from the back portion of right diagonal strut 202 to the top portion of vertical front strut 210. Left diagonal vertical strut 214 extends from the back portion of left diagonal strut 204 to the top portion of vertical front strut 210. Collectively, right and left vertical diagonal struts 212 and 214 help prevent vertical strut 210 from moving, particularly, from rotating front to back or left to right. An intermediate cross strut 216 extends horizontally from right diagonal vertical strut 212 to left diagonal vertical strut 214. Intermediate cross strut 216 stabilizes right and left vertical diagonal struts 214 and 216 and may limit right vertical diagonal strut 214 and left vertical diagonal strut 216 from moving relative to each other.

Apparatus 10 includes joint 300 that rotatably couples solar energy capture device 100 to frame 200. Joint 300 defines pitch axis PA and roll axis RA. In an embodiment, pitch axis PA and roll axis RA are parallel to a plane defined by solar energy capture device 100, and pitch axis PA and roll axis RA are perpendicular. Joint 300 allows solar energy capture device 100 to rotate about pitch axis PA and roll axis RA relative to frame 200.

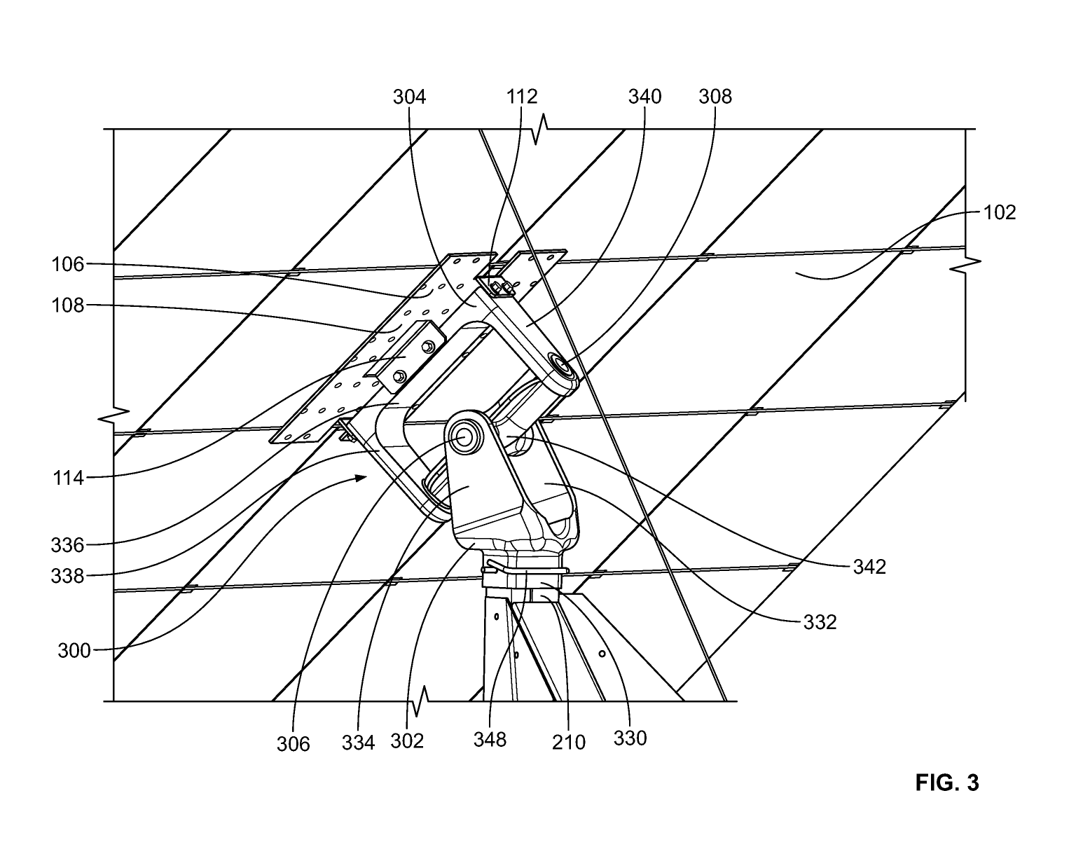

In an embodiment as shown in FIGS. 2-3, joint 300 may comprise a U-joint that allows solar energy capture device 100 to rotate in any direction relative to frame 200. U-joint 300 may include a lower yoke 302 and an upper yoke 304. Lower yoke 302 couples joint 300 to frame 200, for example, at the top portion of vertical strut 210. Upper yoke 304 couples joint 300 to solar energy capture device 100, for example, by interfacing with reinforcement plate 106. In other embodiments, upper yoke 304 may connect directly to solar energy capture device 100.

FIG. 3 illustrates an enlarged perspective view of joint 300 as illustrated in FIG. 2 according to an embodiment of the present invention. Lower yoke 302 can include a hub 330 that defines a hollow channel that corresponds to the shape of vertical strut 210. The top end portion of vertical strut 210 is inserted within hub 330. In one embodiment, lower yoke 302 can be secured to frame 200 by using a retention pin 348. For example, retention pin 348 can pass through a pair of holes in lower hub 330 and an aligned pair of holes in vertical strut 210, securing joint 300 to frame 200.

Extending upward from hub 330 is a pair of opposing arms 332 and 334. Arms 332 and 334 are spaced apart to create a gap in a substantially U-shaped configuration. Upper yoke 304 includes a base portion 336 and a pair of opposing arms 338 and 340 extending from the ends of base portion 336 in a substantially inverted U-shaped configuration. Lower yoke 302 and upper yoke 304 are rotatably coupled together by center portion 342. Center portion 342 can be X-shaped or cross-shaped with a first pair of pins 306 extending from opposing legs of the center portion 342 and a second pair of pins 308 extending from the other pair of opposing legs. Accordingly, second pair of pins 306 are perpendicular to first pair of pins 306. First pair of pins 306 are rotatably coupled to lower yoke 302, for example, by coupling pins 306 with ball bearings seated in openings defined in the top portions of arms 332 and 334. Similarly, second pair of pins 308 are rotatably coupled to upper yoke 304, for example, by coupling pins 308 with ball bearings seated in openings defined in the lower portions of arms 338 and 340.

Upper yoke 304 can be coupled to reinforcement plate 106 of solar energy capture device 100. Reinforcement plate 106 can include a mounting surface 108. Mounting surface 108 is securely coupled to back surface 102 of device 100 using any suitable adhesive or any suitable fasteners. A pair of opposing front and back walls 112 and a pair of opposing side walls 114 extend perpendicularly from mounting surface 108. Front and back walls 112 and side walls 114 define a space that closely corresponds to the shape of base portion 336 of upper yoke 304. Accordingly, base portion 336 can be seated in the space defined by front and back walls 112 and side walls 114. Upper yoke 304 can be secured to reinforcement plate 106 by fasteners extending through front and back walls 112 and side walls 114 into base portion 336 of upper yoke 304 or by any other suitable means of attaching yoke 304 to reinforcement plate 106.

In one embodiment, as shown, for example, in FIG. 3, lower yoke 302 is adapted to allow rotation of solar energy capture device 100 about pitch axis PA and upper yoke 304 is adapted to allow rotation of solar energy capture device 100 about roll axis RA. In this manner, upper yoke 304 may be positioned intermediate to device 100 and lower yoke 302, and lower yoke 302 may be positioned intermediate to upper yoke 304 and frame 200. The relative orientation of upper yoke 304 and lower yoke 302 permit stable rotation of device 100 relative to frame 200.

With reference to FIG. 2, in one embodiment apparatus 10 also includes a first linear actuator 400a and a second linear actuator 400b. Each linear actuator 400a and 400b has a variable length member coupled to solar energy capture device 100. In one embodiment, first and second linear actuators 400a and 400b each comprise a cable actuation mechanism including a motor 402 and a cable 404. Motor 402 can be any suitable motor that can rotate a spool in one direction to spool cable 404 on the spool, which decreases the length of the variable length member, and can rotate the spool in an opposite direction to release cable 404 from the spool, which increases the length of the variable length member. For example, in one embodiment, motor 402 can be a stepper motor having a gear ratio of about 70:1 for spooling cable 404. In other embodiments, other suitable gear ratios may be used. Cable 404 can be made of any suitable material having sufficient strength to apply the necessary forces to solar energy capture device 100, for example, strands of fiber or metal. The distal end of left cable 404 is coupled to solar energy capture device 100 near its left edge, and the distal end of right cable 404 is coupled to solar energy capture device 100 near its right edge. The flexible nature of cables 404 allow cables 404 to rotate relative to solar energy capture device 100, eliminating the requirement that the distal end portion of the variable length member be connected to object 100 by a U-joint or a ball-and-socket joint. For example, cables 404 can be coupled to solar energy capture device 100 using mounting brackets. Each cable 404 can be looped around a mounting pin on mounting bracket 406.

In embodiments using linear actuators having variable length members that cannot withstand compressive forces, for example, cables 404, apparatus 10 can also include a return mechanism that prevents unwanted rotation of object 100 about pitch axis PA toward the variable length member. The return mechanism can be any device capable of applying a force (for example, tension or torsion springs, elastic chords, or linear actuators) or a counter weight (for example, the weight of object 100 or a separate weight coupled to joint 300 below pitch axis PA). In one embodiment, the return mechanism can be the weight of solar energy capture device 100 below pitch axis PA as determined by the location at which joint 300 couples to solar energy capture device 100. For example, as shown in FIG. 2, joint 300 is coupled to solar energy capture device above the center of mass of solar energy capture device 100. In this manner, the weight of the portion of solar energy capture device 100 below the joint 300 and pitch axis PA biases solar energy capture device 100 against rotating about pitch axis PA towards the back of apparatus 10. In embodiments that use a cable actuation mechanism as a linear actuator, the return mechanism can also provide cable tension or preload to prevent the cable from tangling while spooling and releasing.

In some embodiments, the majority of the weight attributed to linear actuators 400a and 400b can be located relatively low on apparatus 10, for example, at the base portion of frame 200. The low center of mass attributed to linear actuators 400a and 400b may allow frame 200 to be lighter, especially at the top, which may decrease the fabrication costs of frame 200 and allow for favorable scaling with increasing the size of object 100.

Apparatus 10 may further include a control unit 500 (not shown in FIG. 2) for operating linear actuators 400a and 400b. During operation, control unit 500 is adapted to send one or more control signals to linear actuators 400a and 400b, causing motors 402 to spin in a desired direction to either spool or release cables 404. To rotate solar energy capture device 100 about pitch axis PA, control unit 500 collectively actuates linear actuators 400a and 400b so that motors 402 spin in a direction that cause cables 404 to be simultaneously spooled (decreasing the length of the variable length members) or simultaneously released (increasing the length of the variable length members). As cables 404 are spooled, solar energy capture device 100 rotates about pitch axis PA towards the back of apparatus 10. Conversely, as cables 404 are released, solar energy capture device 100 rotates about pitch axis PA towards the front of apparatus 10 due to the force of the return mechanism.

To rotate solar energy capture device 100 about roll axis RA, control unit 500 differentially actuates linear actuators 400a and 400b so that one motor 402 spins in a direction that causes its respective cable 404 to be spooled (decreasing the length of the variable length member), and/or so that the other motor 402 spins in a direction that causes its respective cable 404 to be released (increasing the length of the variable length member). For example, as cable 404 of linear actuator 400a is spooled and cable 404 of linear actuator 400b is released, solar energy capture device 100 rotates about roll axis RA towards the left of apparatus 10. Conversely, as cable 404 of linear actuator 400a is released and cable 404 of linear actuator 400b is spooled, solar energy capture device 100 rotates about roll axis RA towards the right of apparatus 10.

Accordingly, the pitch angle and the roll angle of solar energy capture device 100 can be changed by a combination of collectively and/or differentially actuating linear actuators 400a and 400b.

In some embodiments in which solar energy capture device 100 is a mirror assembly 100 for a thermal system, the mirror assembly may include a mirror structure particularly adapted for edge actuation provided by embodiments of the present invention. In one embodiment, linear actuators 400a and 400b may be coupled to the solar energy capture device 100 at points more proximate to the edge of the mirror structure than the center point of the mirror structure. This configuration may provide an increased lever arm that may increase the effective actuator force (i.e., torque) on the mirror. In such an embodiment, the mirror structure may be adapted to have additional strength and stiffness proximate to its edges to accommodate edge actuation without breaking or defocusing. In some embodiments in which the mirror assembly is mounted to universal joint 300, the attachment may be provided such that the loading around the reinforcement plate 106 is symmetric. In this manner, joint 300 will not pivot on its own absent actuation forces from linear actuators 400a and 400b. In such an embodiment, the stiffness of the mirror structure may be less at the joint attachment location (e.g., at reinforcement plate 106) than at the edges of the mirror structure. In contrast, a center actuated mirror must be very strong around the joint mount location to avoid stress concentration at the edge of the bracket. Accordingly, in some embodiments of the present invention, the mirror structure may be thicker at a point proximate its edge than at a point proximate the joint attachment location to provide effective edge actuation.

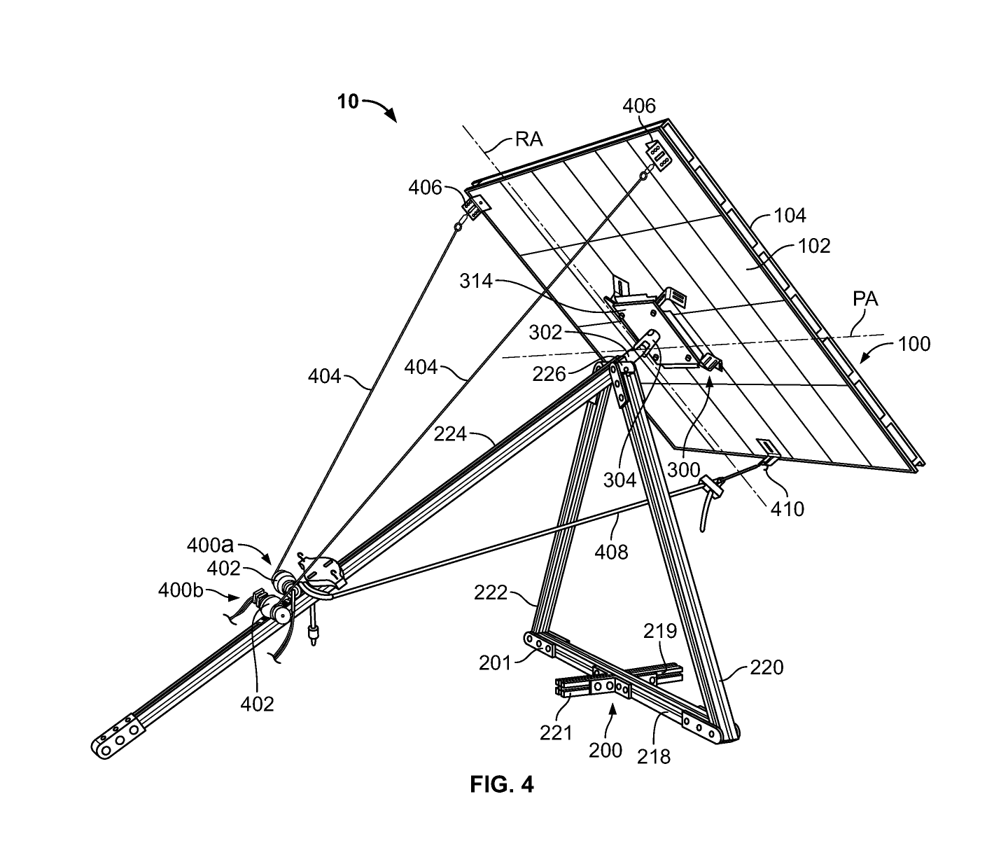

FIG. 4 illustrates apparatus 10 according to an embodiment of the present invention. To the extent the illustrated embodiment in FIG. 4 shares similar features as described above regarding FIGS. 1-3, similar reference numbers are used. In this embodiment, object 100 can be a solar energy capture device. Frame 200 includes a base portion 201 having a base cross strut 218 configured to contact the mounting surface, for example, the ground. Extending forward from the midpoint of base cross strut 218 is longitudinal strut 219, which helps prevent frame 200 from tilting forward. Extending backward from the midpoint of base cross strut 218 is longitudinal strut 221, which helps prevent frame 200 from tilting backward. Extending upward from one end of cross base strut 218 is a right diagonal support 220, and extending upward from the other end of cross bass strut 218 is left diagonal support 222. The top portion of right diagonal support 220 and the top portion of left diagonal support 222 intersect at apex 226. A longitudinal diagonal strut 224 extends backwards and downwards from apex 226. The bottom portion of diagonal strut 224 is configured to contact the mounting surface.

As shown in FIG. 4, joint 300 may be a U-joint similar to the joint discussed above regarding FIG. 3. Joint 300 includes a lower yoke 302 extending forward from apex 226. Joint 300 may also include a reinforcement plate 314. One side of reinforcement plate 314 is coupled to solar energy capture device 100 by adhesive, fasteners, or any other suitable attachment method. For example, as shown in FIG. 4, reinforcement plate 314 can be mounted to device 100 using brackets that are fastened to the back side 102 of device 100. The back side of reinforcement plate 314 is coupled to upper yoke 304. Upper yoke 304 is rotatably coupled to lower yoke 302.

In another embodiment, joint 300 may be a ball and socket joint. In this embodiment, joint 300 includes an arm extending from apex 226. The front portion of the arm defines a ball or spherical surface. Joint 300 further comprises reinforcement plate 314 having one side coupled to solar energy capture device 100. The other side of reinforcement plate 314 defines a socket that has a shape that corresponds to the ball defined by arm 310. The socket captures the ball of the arm, allowing plate 314 and, thus, solar energy capture device 100 to rotate relative to the arm and frame 200. Alternatively, the arm can define a socket that captures a ball defined by reinforcement plate 314.

As illustrated in FIG. 4, joint 300 can be coupled to solar energy capture device 100 at or below the center of mass of the solar energy capture device 100. In this embodiment, apparatus 10 includes a return mechanism that prevents solar energy capture device 100 from completely rotating about pitch axis PA towards the back of apparatus 10. In one embodiment, the return mechanism is an elastic member 408 that prevents solar energy capture device 100 from rotating completely about pitch axis PA. Elastic member 408 is coupled to the bottom edge of solar energy capture device 100 using a mounting bracket 410. On the other end, elastic member 408 is coupled to a portion of frame 200, for example, a middle portion of diagonal strut 224. As cables 404 are spooled, elastic member 408 stretches to allow solar energy capture device 100 to rotate about pitch axis PA towards the back, but prevents complete rotation about pitch axis PA. As cables 404 are released or lengthened, elastic member 408 provides a tension force causing solar energy capture device 100 to rotate about pitch axis PA towards the front.

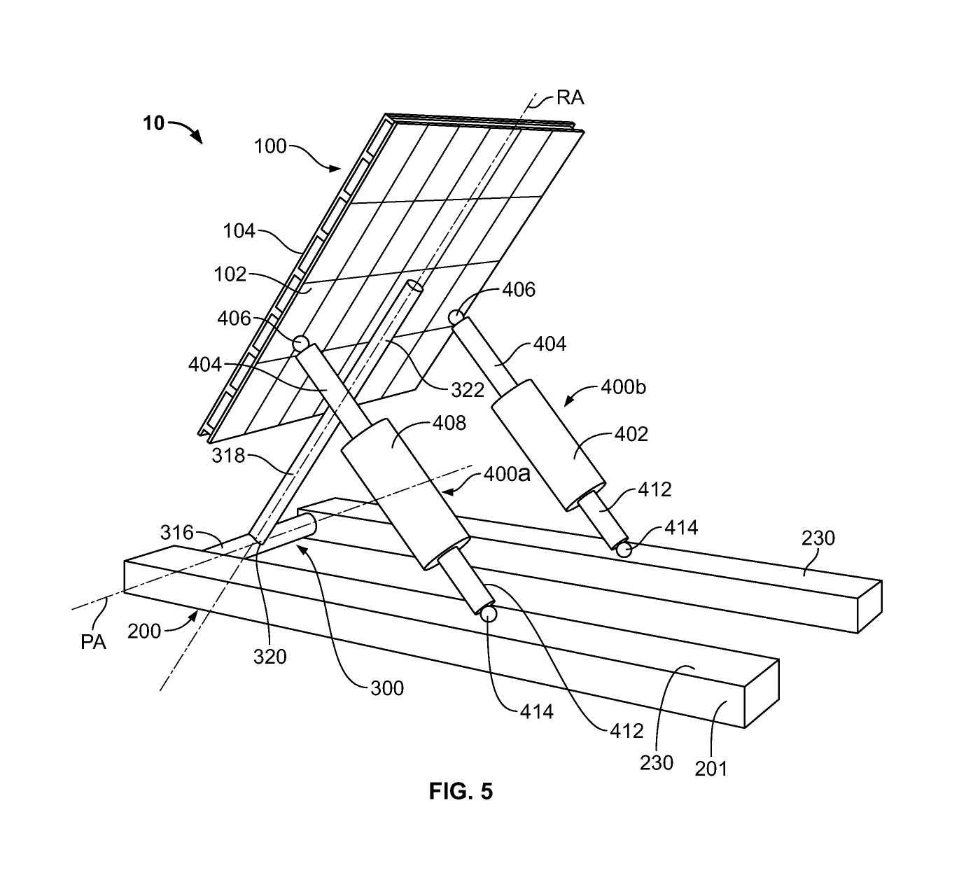

FIG. 5 illustrates apparatus 10 according to an embodiment of the present invention. To the extent the illustrated embodiment in FIG. 5 shares similar features as described above regarding FIGS. 1-4, similar reference numbers are used. As shown in FIG. 5, frame 200 includes a base portion 201 having a pair of longitudinal struts 230 that are spaced apart. Struts 230 are configured to contact the mounting surface. Joint 300 can include a horizontal rotating member 316 and a vertical rotating member 318. Horizontal rotating member 316 defines pitch axis PA about which it can rotate. Each end of horizontal rotating member 316 is rotatably coupled to longitudinal struts 230, for example, by using bushings or bearings. Vertical rotating member 318 defines roll axis RA about which it can rotate. Vertical rotating member 318 is rotatably coupled to horizontal rotating member 316 at joint 320, for example, by using bushings or bearings. The upper portion 322 of vertical rotating member 318 is coupled to solar energy capture device 100 by any suitable means, for example, U-brackets, fasteners, adhesives, or any other suitable means. In one embodiment, horizontal rotating member 316 may be positioned below vertical rotating member 318. In this manner, horizontal rotating member 316 may be a lower rotating member and vertical rotating member 318 may be an upper rotating member. In other embodiments, for example, wherein frame 200 may be attached to an overhead surface, horizontal rotating member 316 may be positioned above vertical rotating member 318.

As shown in FIG. 5, linear actuators 400a and 400b can be hydraulic piston assemblies. Hydraulic piston assemblies 400a and 400b each include a cylinder 402 and a linearly reciprocating piston 404. Each piston assembly can have a fixed length mounting stem 412 that rotatably couples to longitudinal strut 230. In one embodiment, the lower portion of mounting stem 412 forms a ball and socket joint 414 with longitudinal strut 230. In other embodiments, each piston assembly can be coupled to longitudinal strut 230 using a one-dimensional pivot, limiting rotation of the piston assembly. The upper portion of piston 404 can be rotatably coupled to an edge of solar energy capture device 100, for example, by a ball and socket joint 406. Ball and socket joints 406 and 414 allow piston assemblies 400a and 400b to rotate in any direction relative to solar energy capture device 100. Accordingly, collective actuation of piston assemblies 400a and 400b causes piston 404 to simultaneously change lengths, which causes solar energy capture device 100 to rotate about pitch axis PA as horizontal rotating member 316 rotates relative to frame 200. Differential actuation of piston assemblies 400a and 400b causes solar energy capture device to rotate about roll axis RA as vertical rotating member 318 rotates relative to horizontal rotating member 316. In some embodiments, because pistons 404 are generally rigid, a separate return mechanism is not needed if the hydraulic pressure is maintained.

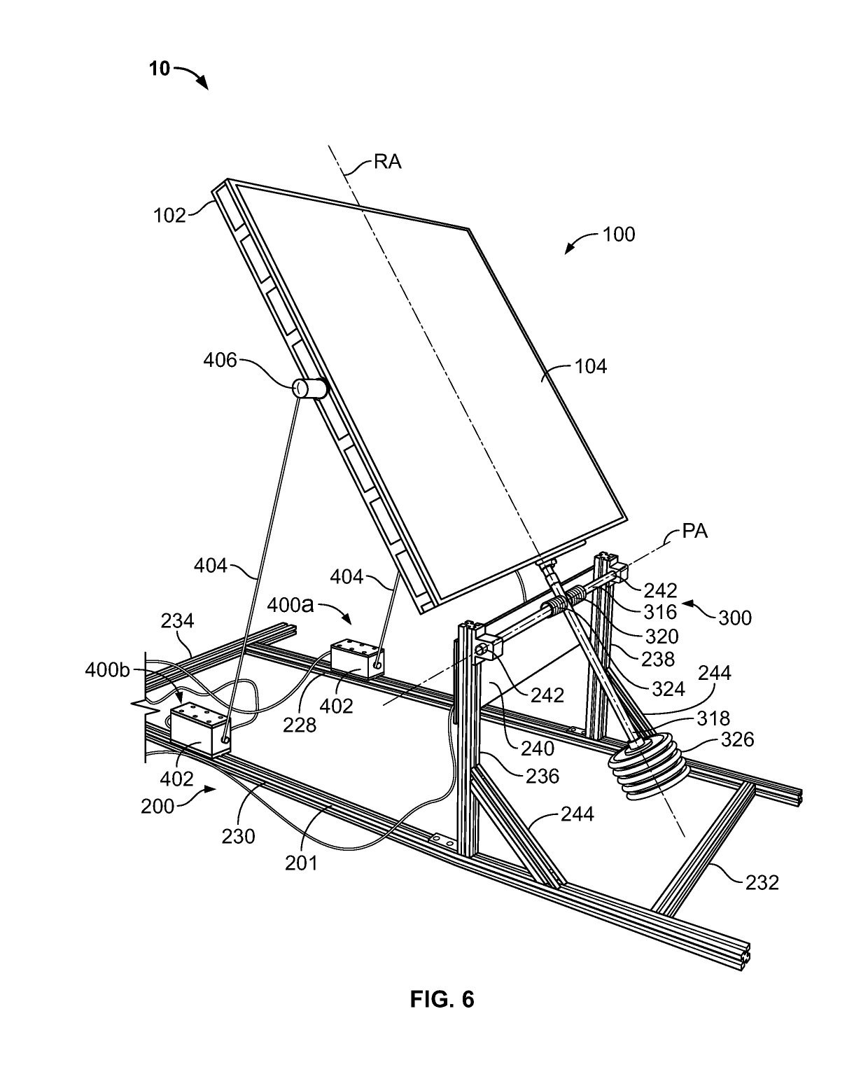

FIG. 6 illustrates a front perspective view of apparatus 10 according to an embodiment. To the extent the illustrated embodiment in FIG. 6 shares similar features as described above regarding FIGS. 1-5, similar reference numbers are used. Frame 200 includes a base portion 201 having a pair of longitudinal struts 230 that are spaced apart by a pair of cross struts 232 and 234. A pair of vertical struts 236 and 238 extend upward from the right and left longitudinal struts 230. To provide additional support the angle between the vertical struts 236 and 238 and the respective longitudinal struts 230 can be buttressed by diagonal struts 244 running there between. Between right and left vertical struts 236 and 238 is cross support 240, for example, a plate as shown in FIG. 6. Similar to the embodiment illustrated in FIG. 5, joint 300 includes horizontal rotating member 316 and a vertical rotating member 318. Horizontal member 316 rotatably couples with vertical struts 236 and 238 at joints 242, for example, ball bearings or bushings.

As illustrated in FIG. 6, linear actuators 400a and 400b are cable actuation mechanisms each including motor 402 and cable 404. In this embodiment, apparatus 10 may include a return mechanism as described above. In one embodiment, the return mechanism can be a counter weight 326, a torsion spring 324, or both. The weight of counter weight 326 or the applied force of torsion spring 324 applies a moment about pitch axis PA to vertical rotating member 318, biasing it and coupled solar energy capture device 100 to rotate towards the front. Cables 404 prevent complete forward rotation about pitch PA. When the return mechanism comprises a counter weight, horizontal rotating member 316 can be elevated such that a portion of vertical rotating member 318 can extend below horizontal rotating member 316 and pitch axis PA without interfering with the mounting surface.

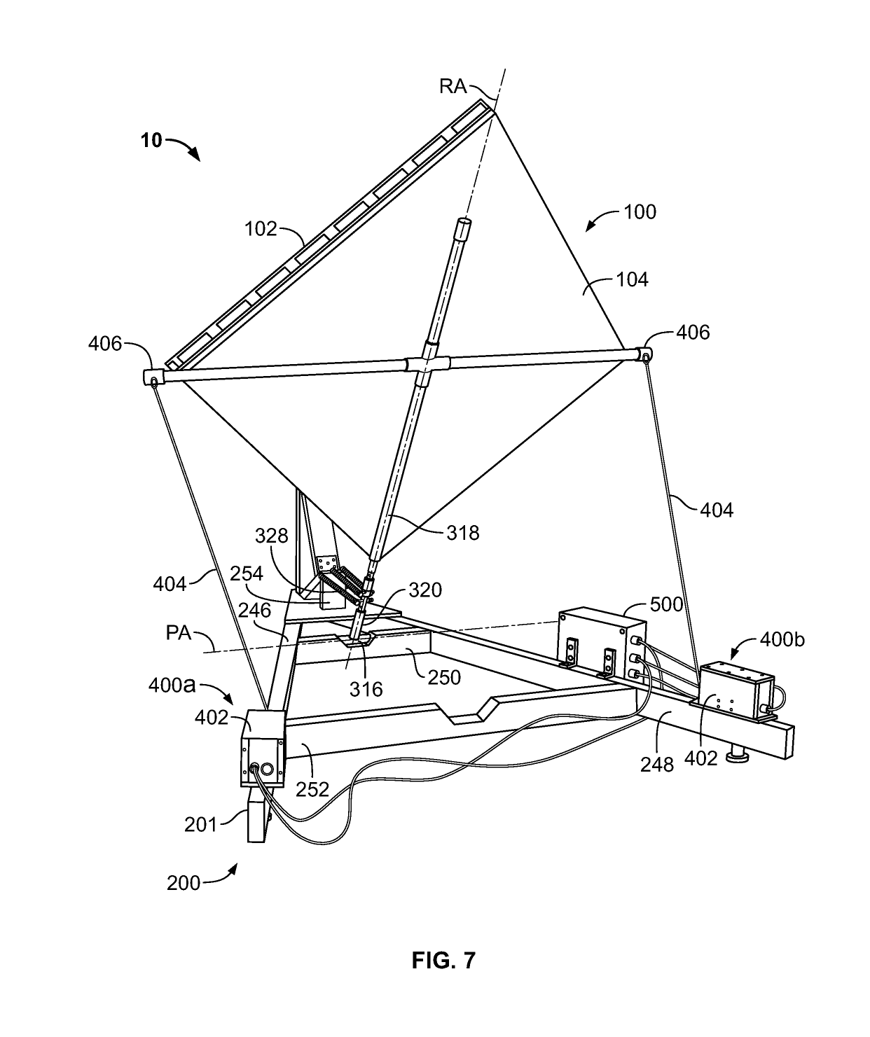

FIG. 7 illustrates a back perspective view of apparatus 10 according to an embodiment. To the extent the illustrated embodiment in FIG. 7 shares similar features as described above regarding FIGS. 1-6, similar reference numbers are used. Frame 200 includes a base portion 201 having two converging side struts 246 and 248, forming a substantially V-shaped configuration. Base portion 201 may also include a front cross support 250 extending between struts 246 and 248 near the front of frame 200. Base portion 201 may further include a back cross support 252 extending between struts 246 and 248 near the back or middle of frame 200. Cross support 250 can define a recess at its center for seating horizontal rotating member 316, which is rotatably coupled to frame 200 therein. A front strut 254 can extend upward from the front of frame 200. In one embodiment, the return mechanism can be a tension spring 328. One end of spring 328 is coupled to vertical front strut 254, and the other end of spring 328 is coupled to rotating vertical member 318. Spring 328 applies a force to create a moment about pitch axis PA to vertical member 318, biasing vertical member 318 to rotate about pitch axis PA. As shown in FIG. 7, control unit 500 can be mounted on frame 200 and operatively connected to linear actuators 400a and 400b.

In some embodiments having a square or rectangular object 100, object 100 can be coupled to joint 300 and frame 200 in an orthogonal configuration as shown in FIGS. 2 and 4-6 or a diamond configuration as shown in FIG. 7. Mounting a square or generally rectangular object in an orthogonal configuration improves field packing density, but may limit ground clearance and range of motion. Mounting a square or generally rectangular object in a diamond configuration may improve ground clearance and range of motion.

In one embodiment, apparatus 10 can include a third linear actuator. The third linear actuator can be coupled to object 100 at a point below pitch axis PA. Accordingly, the third linear actuator can function as the return mechanism.

In an embodiment having joint 300 that includes a horizontal rotating member 316 and a vertical rotating member 318, linear actuators 400a and 400b can be replaced with a motor embedded within or operatively connected to horizontal rotating member 316, and a motor embedded within or operatively connected to vertical rotating member 318. Activation of the motor connected to the horizontal rotating member 316 causes object 100 to rotate about pitch axis PA, and activation of the motor connected to the vertical rotating member 318 causes object 100 to rotate about roll axis RA.

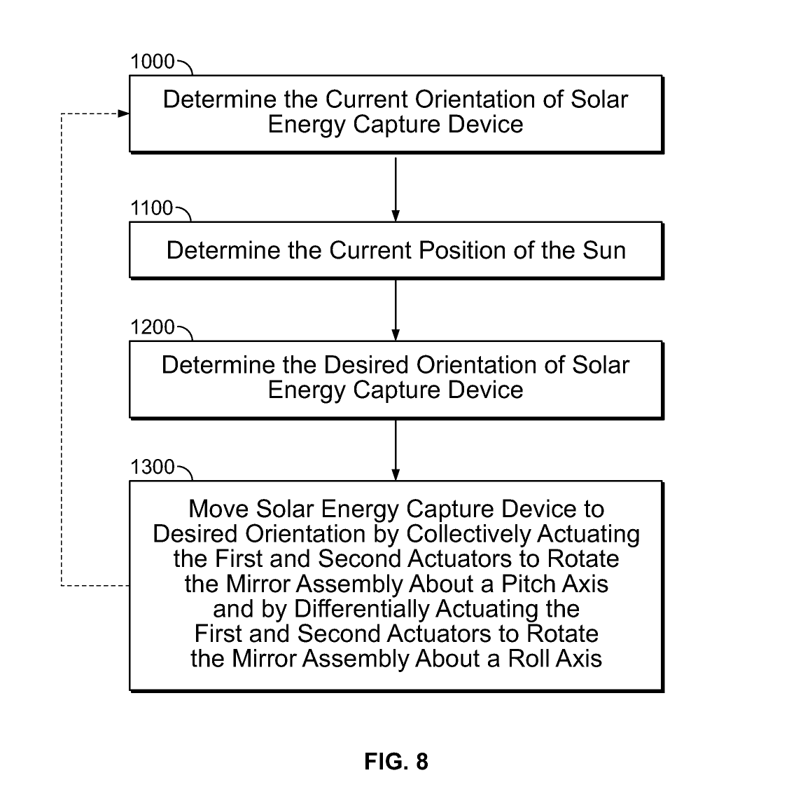

FIG. 8 illustrates a block diagram depicting a method of positioning a solar energy capture device 100 according to an embodiment. In step 1000, the current orientation of solar energy capture device 100 is determined relative to one or more of frame 200, pitch axis PA, and/or roll axis RA. In one embodiment, the current orientation of solar energy capture device 100 may be provided relative to a default or “home” position of the device. In one embodiment, the current orientation of solar energy capture device 100 is determined by using a sensor, for example, one or more proximity sensors. In one embodiment, the proximity sensors can be located on the base portion of frame 200. In embodiments having a horizontal rotating member and a vertical rotating member, the proximity sensor(s) can be located on the horizontal and vertical rotating members. In some embodiments, a proximity sensor may be disposed on object 100. In one embodiment, the proximity sensor(s) may comprise an accelerometer. The proximity sensor is in communication with the control unit and is adapted to provide real time position information.

In step 1100, the current position of the sun is determined. For example, in one embodiment, the position of the sun is determined by known orbital patterns determined by date. As will be appreciated, the current position of the sun may be determined by one or more data elements including, but not limited to, date, time, and geographic location (e.g., latitude and longitude coordinates). In another embodiment, the position of the sun is determined by using a sensor.

Using the current position of the sun determined at step 1100, a desired orientation of the solar energy capture device is determined at step 1200. For example, if solar energy capture device 100 is a mirror assembly for a thermal system, the desired orientation can be one that positions the mirror assembly so that the reflected light is focused on a receiver. If solar energy capture device 100 is a photovoltaic panel, the desired orientation can be, for example, a position that orients the photovoltaic panel to be perpendicular to the incident light from the sun.

At step 1300, solar energy capture device 100 is moved to the determined desired position by collectively actuating the first and second actuators to rotate the mirror assembly about a pitch axis and by differentially actuating the first and second actuators to rotate the mirror assembly about a roll axis. Consequently, solar energy capture device 100 can be positioned at an orientation having a desired pitch angle and roll angle.

In one embodiment, control unit 500 can perform steps 1000, 1100, and 1200, and control the actuation in step 1300. In some embodiments, the method is repeated after a predetermined time interval, for example, every thirty minutes, every hour, every other hour, or any other suitable time interval. In some embodiments, positioning of solar energy capture device 100 is continuously updated in real-time.

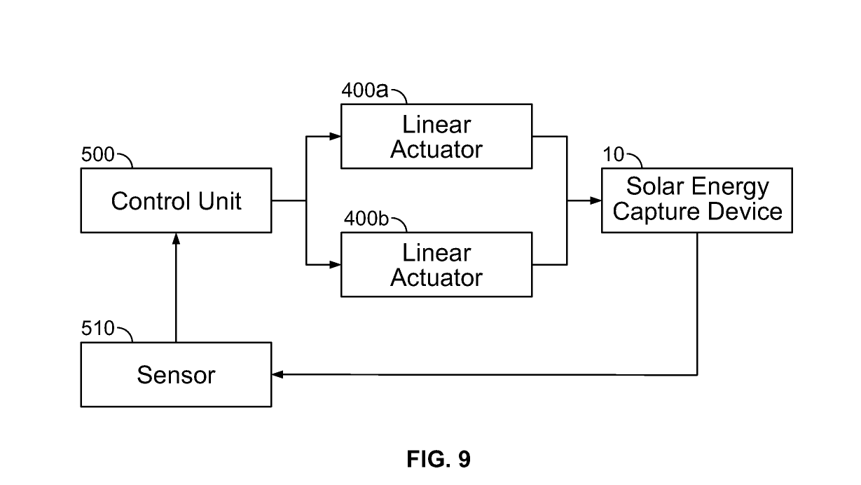

FIG. 9 illustrates a block diagram depicting a closed loop configuration for moving solar energy capture device 100 according an embodiment. As illustrated in FIG. 9, control unit 500 is operatively connected to linear actuators 400a and 400b such that control unit 500 can collectively or differentially actuate linear actuators 400a and 400b. After determining the desired position of solar energy capture device 100 (step 1200), control unit 500 actuates linear actuator 400a and 400b collectively to rotate solar energy capture device 100 about pitch axis PA and/or differentially to rotate solar energy capture device 100 about roll axis RA. In one embodiment, a sensor 510 monitors the current position of solar energy capture device 100 (step 1000) and communicates the position to control unit 500. Control unit 500 compares the current position of solar energy capture device 100 as communicated by sensor 510 to the desired position of the solar energy capture device 100. Control unit 500 continues to actuate linear actuators 400a and 400b, either collectively or differentially, until the current position equals the desired position. Once this result occurs, control unit 500 may cease actuation of linear actuators 400a and 400b.

In another embodiment, instead of determining an absolute desired orientation from the current position of the sun, for example, a desired rate and direction of orientation change of the device 100 can be determined. Accordingly, knowing the geometry of apparatus 10, control unit 500 can be programmed to move device 100 at the desired rate and direction by controlling the length and rate of change of the variable length member of each linear actuator 400.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. For example, although the figures illustrate the object 100 as a solar energy capture device, apparatus 10 can be adapted to position other objects such as communication antennas, weapon platforms, and directed-energy appliances, for example. Therefore, such adaptations and modifications are intended to be within the meaning and range of equivalents of the disclosed embodiments, based on the teaching and guidance presented herein.

It is to be understood that the phraseology or terminology herein is for the purpose of description and not of limitation, such that the terminology or phraseology of the present specification is to be interpreted by the skilled artisan in light of the teachings and guidance. The breadth and scope of the present invention should not be limited by any of the above-described exemplary embodiments, but should be defined only in accordance with the following claims and their equivalents.

What is claimed is:

1. An apparatus for receiving sunlight, comprising:
a frame;
a solar energy capture device;
a joint connected to the solar energy capture device and the frame to allow rotation of the solar energy capture device relative to the frame; and
first and second linear actuators coupled to the solar energy capture device for positioning the solar energy capture device, wherein the first and second actuators actuate in combination to rotate the solar energy capture device about a pitch axis, and wherein the first and second actuators actuate differentially to rotate the solar energy capture device about a roll axis.

2. The apparatus of claim 1, wherein the first and second actuators each include a first end attached to the frame and a second end attached to the solar energy capture device.

3. The apparatus of claim 1, wherein at least one of the first and second actuators comprises a variable length cable.

4. The apparatus of claim 1, wherein at least one of the first and second actuators comprises a hydraulic piston.

5. The apparatus of claim 1, wherein at least one of the first and second actuators comprises a scissor jack.

6. The apparatus of claim 1, wherein at least one of the first and second actuators comprises a linear screw drive.

7. The apparatus of claim 1,
wherein at least one of the first and second linear actuators include a motor for actuating the at least one of the first and second linear actuators; and
the apparatus further comprising a control unit for controlling the motor to position the solar energy capture device in response to a change in position of the sun.

8. The apparatus of claim 7, wherein the solar energy capture device is a mirror assembly, and wherein the control unit controls the motor to position the mirror assembly to direct sunlight reflected from the mirror assembly on a receiver.

9. The apparatus of claim 7, wherein the solar energy capture device is a photovoltaic panel, and wherein the control unit controls the motor to position the photovoltaic panel to be perpendicular to incident sunlight.

10. The apparatus of claim 7, wherein the control unit includes a sensor for determining an orientation of the solar energy capture device.

11. The apparatus of claim 1, wherein the joint comprises a universal joint connected to a back side of the solar energy capture device to allow rotation of the solar energy capture device about the pitch axis and the roll axis.

12. The apparatus of claim 1, wherein the joint is connected to the solar energy capture device above the center of mass of the solar energy capture device.

13. The apparatus of claim 1 further comprising a return mechanism configured to apply a force to the solar energy capture device in a direction opposite to a force applied by the first and second linear actuators.

14. The apparatus of claim 13, wherein the return mechanism comprises a third linear actuator.

15. The apparatus of claim 1, wherein the joint comprises:
an upper rotating member connected to a back side of the solar energy capture device to allow rotation of the solar energy capture device about the roll axis; and
a lower rotating member connected to the upper rotating member and the frame to allow rotation of the solar energy capture device about the pitch axis.

16. The apparatus of claim 1, wherein the frame includes a V-shaped base.

17. The apparatus of claim 1, wherein the solar energy capture device comprises a mirror assembly having at least one reflector for reflecting sunlight onto a receiver.

18. An apparatus for receiving sunlight, comprising:
a frame having a lateral axis and a longitudinal axis therethrough;
a solar energy capture device;
a joint assembly connected to the solar energy capture device and the frame to allow rotation of the solar energy capture device relative to the frame, wherein the joint assembly includes
a lower portion connected to the frame to allow rotation of the solar energy capture device about an axis parallel to the lateral axis, and
an upper portion connected to the solar energy capture device and the lower portion to allow rotation of the solar energy capture device about an axis planar with the longitudinal axis;
a first variable length actuator having a first pivot end coupled to the solar energy capture device on a first side of the joint assembly; and
a second variable length actuator having a second pivot end coupled to the solar energy capture device on a second side of the joint assembly opposite the first pivot end,
wherein the first and second actuators actuate in combination to rotate the solar energy capture device about the axis parallel to the lateral axis, and wherein the first and second actuator members actuate differentially to rotate the solar energy capture device about the axis planar with the longitudinal axis.

19. The apparatus of claim 18, wherein the first and second pivot ends are disposed above the joint assembly.

20. The apparatus of claim 18, wherein the first and second pivot ends are disposed between the joint assembly and an outer edge of the solar energy capture device.

21. The apparatus of claim 18, wherein the joint assembly is disposed above the center of mass of the solar energy capture device.

22. The apparatus of claim 18, wherein the solar energy capture device comprises a mirror assembly having at least one reflector for reflecting sunlight onto a receiver.

23. The apparatus of claim 18, wherein the solar energy capture device comprises a photovoltaic panel.

24. An apparatus for positioning an object at desired pitch angle and a desired roll angle, comprising:
a frame;
an object;
a joint connected to the object and the frame to allow rotation of the object relative to the frame; and
a first linear actuator having a first variable length member, the first linear actuator being coupled to the object and the frame; and
a second linear actuator having a second variable length member, the second linear actuator being coupled to the object and the frame,
wherein the lengths of the first and second variable length members are simultaneously and equally changed to rotate the object about a pitch axis, and wherein the length of the first variable length member is differentially changed relative to the length of the second variable length member to rotate the object about a roll axis.

25. The apparatus of claim 24, wherein the object is a solar energy capture device.

26. A method for positioning a solar energy capture device, comprising:
moving the solar energy capture device to a desired orientation by collectively actuating first and second linear actuators to rotate the solar energy capture device about a pitch axis and by differentially actuating the first and second linear actuators to rotate the solar energy capture device about a roll axis,
wherein the first and second linear actuators are coupled to the solar energy capture device and a frame.

27. The method of claim 26, wherein the desired orientation of the solar energy capture device is determined from the current position of the sun.

28. The method of claim 26, wherein the solar energy capture device is moved to a second desired orientation after a predetermined time period.

29. The method of claim 26 further comprising:
determining the current orientation of the solar energy capture device; and
ceasing actuating of the first and second linear actuators when the current orientation of the solar energy capture device equals the desired orientation.
